(19) United States
(12) Patent Application Publication
(10) Pub. No.: US 2026/0038780 A1
(43) Pub. Date: Feb. 5, 2026

(54) PLASMA PROCESSING APPARATUS AND PLASMA PROCESSING METHOD

(71) Applicant: Samsung Electronics Co., Ltd., Suwon-si (KR)

(72) Inventor: Manabu NAKAGAWASAI, Yokohama-shi (JP)

(73) Assignee: Samsung Electronics Co., Ltd., Suwon-si (KR)

(21) Appl. No.: 19/085,183

(22) Filed: Mar. 20, 2025

(30) Foreign Application Priority Data
Jul. 30, 2024 (JP) 2024-122980
Nov. 5, 2024 (KR) 10-2024-0155547

(51) Int. Cl. H01J 37/32; H01J 37/244

(52) U.S. Cl. CPC H01J 37/32917; H01J 37/244; H01J 37/3244; H01J 2237/2445

(57) ABSTRACT

Example embodiments are directed to a plasma processing apparatus and a plasma processing method for improving processing precision. The plasma processing apparatus includes a stage having a mounting surface configured to mount a substrate, an active species emitting unit configured to emit active species or an active species raw material in the direction of the stage for performing plasma processing on the substrate, a laser light generation unit configured to form a laser sheet in an observation region of the plasma processing apparatus and including at least a portion of a region between the mounting surface and the active species emitting unit, and a detection unit configured to detect excited luminescence generated in the observation region. A quenching time period of the excited luminescence is 20 nanoseconds or less.

### CROSS-REFERENCE TO RELATED APPLICATIONS

This U.S. non-provisional application claims priority under 35 U.S.C. § 119 to Japanese Patent Application No. 2024-122980 filed on Jul. 30, 2024, in the Japanese Intellectual Property Office and Korean Patent Application No. 10-2024-0155547, filed on Nov. 5, 2024, in the Korean Intellectual Property Office, the entire contents of both these applications are incorporated herein by reference.

### BACKGROUND

Example embodiments are directed to a plasma processing apparatus and a plasma processing method.

Plasma processing is performed on a substrate, such as a semiconductor substrate. Plasma processing may include, for example, etching processing and film processing using plasma. It is beneficial to have higher or improved precision in plasma processing. For example, in the field of an image sensor, the pixel count is relatively higher and it may be advantageous to have improved precision when processing a substrate for manufacturing image sensors. Semiconductor device processing techniques such as etching, film formation, impurity injection, and the like may be used for forming a relatively higher aspect inter-pixel separation layer.

For example, in order to improve processing precision, relatively smaller and/or finer adjustments may be made to a processing recipe using information or data obtained from various sensors of the plasma processing apparatus. The various sensors may be sensors for controlling plasma processing conditions, and detecting, for example, pressure, flow rate, atomic emission intensity, and the like. The finer adjustments of the processing recipe may be performed, for example to vary a temperature, a voltage, a frequency, and the like.

### SUMMARY

It is beneficial to improve or optimize processing precision by detecting an active species produced during the plasma processing. The active species may refer to the gas used in plasma processing.

Example embodiments of the inventive concepts are directed to a plasma processing apparatus and a plasma processing method for improving and/or optimizing processing precision.

According to some example embodiments of the inventive concepts, a plasma processing apparatus may include a stage having a mounting surface configured to mount a substrate, an active species emitting unit configured to emit an active species or an active species raw material in a direction of the stage for performing plasma processing on the substrate, a laser light generation unit configured to form a laser sheet in an observation region of the plasma processing apparatus that includes at least a portion of a region between the mounting surface and the active species emitting unit, and a detection unit configured to detect excited luminescence generated in the observation region. A quenching time period of the excited luminescence may be 20 nanoseconds or less.

According to some example embodiments of the inventive concepts, in the plasma processing apparatus, the excited luminescence may be generated by the active species excited by the laser sheet.

According to some example embodiments of the inventive concepts, the plasma processing apparatus may further include a chamber configured to accommodate the stage and the active species emitting unit.

According to some example embodiments of the inventive concepts, the chamber includes by-products generated by the plasma processing, and the excited luminescence may be generated based on the by-products excited by the laser sheet.

According to some example embodiments of the inventive concepts, the laser light generation unit is configured to form a main surface of the laser sheet in a direction intersecting the mounting surface.

According to some example embodiments of the inventive concepts, the laser light generation unit is configured to form a main surface of the laser sheet in a direction parallel to the mounting surface.

According to some example embodiments of the inventive concepts, the laser light generation unit may be configured to change a wavelength of light comprising the laser sheet.

According to some example embodiments of the inventive concepts, the laser light generation unit may include a light source configured to emit a beam of light and a lens unit configured to form the laser sheet from the beam of light.

According to some example embodiments of the inventive concepts, the plasma processing apparatus may further include a reflector. The laser sheet may include a first portion and a second portion adjacent to each other with the reflector therebetween, and a main surface of the second portion may be in a direction intersecting a main surface of the first portion.

According to some example embodiments of the inventive concepts, a width of the laser sheet may be 50 mm or less.

According to some example embodiments of the inventive concepts, the plasma processing apparatus may further include a damper at or adjacent an end of the laser sheet.

According to some example embodiments of the inventive concepts, the detection unit may face a main surface of the laser sheet.

According to some example embodiments of the inventive concepts, the detection unit may include a single-photon avalanche diode (SPAD).

According to some example embodiments of the inventive concepts, the plasma processing apparatus includes a plurality of stages.

According to some example embodiments of the inventive concepts, the plasma processing apparatus may further include a shutter configured switch between a closed state in which the shutter covers the mounting surface and an open state in which the shutter exposes the mounting surface.

According to some example embodiments of the inventive concepts, the plasma processing apparatus may further include an information processing unit configured to generate a first active species information regarding a state of the active species based on a first luminescence information regarding the excited luminescence captured at a first point in time.

According to some example embodiments of the inventive concepts, the information processing unit may be configured to determine a first condition of the plasma processing, based on the generated first active species information, the information processing unit may be configured to generate a second active species information regarding the state of the active species based on a second luminescence information regarding the excited luminescence captured at a second point in time later than the first point in time, and the information processing unit may be configured to change the first condition based on the generated second active species information.

According to some example embodiments of the inventive concepts, the information processing unit is configured to determine a second condition different from the first condition of the plasma processing.

According to some example embodiments of the inventive concepts, the plasma processing may be etching processing.

According to some example embodiments of the inventive concepts, a plasma processing method may include emitting an active species or an active species raw material from an active species emitting unit in a direction of a stage that is configured to mount a substrate, forming a laser sheet in an observation region including at least a portion of a region between a mounting surface of the stage and the active species emitting unit, and detecting excited luminescence generated in the observation region. A quenching time period of the excited luminescence may be 20 nanoseconds or less.

According to some example embodiments of the inventive concepts, a plasma processing apparatus may include a chamber, a stage within the chamber and having a mounting surface configured to mount a substrate, a nozzle within the chamber and configured to emit an active species or an active species raw material for performing plasma processing on the substrate in a direction of the stage, a laser light generation unit adjacent to the chamber and configured to form a laser sheet in an observation region that includes at least a portion of a region between the mounting surface and the nozzle, and a detection unit configured to detect excited luminescence generated in the observation region. A quenching time period of the excited luminescence may be 20 nanoseconds or less.

According to some example embodiments of the inventive concepts, a plasma processing apparatus may include a chamber, a plurality of stages within the chamber and each having a mounting surface configured to mount a substrate, a plurality of nozzles within the chamber and configured to emit an active species or an active species raw material in a direction of each of the plurality of stages for performing plasma processing on the substrate, a laser light generation unit between the plurality of stages and including a beam splitter or a flip lens configured to form a laser sheet in an observation region that includes at least a portion of a region between the mounting surfaces and the nozzles, and a detection unit configured to detect excited luminescence generated in the observation region. A quenching time period of the excited luminescence may be 20 nanoseconds or less.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram illustrating an example of the configuration of a plasma processing apparatus according to some example embodiments of the inventive concepts.

FIG. 2A illustrates a configuration of a front surface of the chamber, according to some example embodiments.

FIG. 2B illustrates a cross-sectional configuration taken along line B-B of FIG. 2A, according to some example embodiments.

FIG. 3A illustrate a shutter used in the plasma processing apparatus, according to some example embodiments.

FIG. 3B is a plan view illustrating the shutter of FIG. 3A.

FIG. 4A is a side view of the laser light generation unit of FIG. 1, according to some example embodiments.

FIG. 4B is a plan view of the laser light generation unit of FIG. 4A.

FIG. 5 is a block diagram illustrating an example of the configuration of the detection unit of FIG. 1, according to some example embodiments.

FIG. 6 is a block diagram illustrating an example of the configuration of the information processing unit of FIG. 1, according to some example embodiments.

FIG. 7 is a block diagram illustrating an example of the functional configuration of the information processing unit of FIG. 1, according to some example embodiments.

FIG. 8 is a flow chart illustrating a processing method performed by the information processing unit of FIG. 1, according to some example embodiments.

FIG. 9A illustrates a configuration of a front surface of a plasma processing apparatus, according to some example embodiments.

FIG. 9B illustrates a cross-sectional view taken along line B-B of FIG. 9A.

FIG. 10 is a cross-sectional view illustrating a configuration of a plasma processing apparatus, according to some example embodiments.

FIG. 11 is a cross-sectional view illustrating a configuration of a plasma processing apparatus, according to some example embodiments.

### DETAILED DESCRIPTION

Hereinafter, some example embodiments of the inventive concepts will be described in detail with reference to the attached drawings. In the following drawings, the same reference numerals represent the same components, and the sizes of each component in the drawings may be expressed at a different ratio than in reality for clarity and convenience of explanation. Meanwhile, the example embodiments described below are merely exemplary, and various modifications may be made from such example embodiments.

Hereinafter, the terms “upper portion” or “on” may include not only being in contact with and directly above, but also being above in a non-contact manner.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

As used herein, to “monitor” may be to watch, observe, or check something for a special purpose over a period of time. The “monitoring” may occur periodically over the period of time, or the monitoring may occur continuously over the period of time.

A component expressed in the singular includes plural components unless the context clearly indicates otherwise. In addition, when a portion “includes” or “has” a component, it does not exclude other components unless otherwise specifically stated, and it means that it may additionally include other components.

In addition, the use of the term “above” and similar demonstrative terms applies to both singular and plural.

For the operations in a method, if the order is explicitly stated or if there is no contrary statement, the operations are executed in the appropriate order. It is not necessarily limited to the order in which the operations are described. The use of any examples or exemplary terms (e.g., etc.) is intended merely to illustrate technical ideas and is not intended to limit the scope of the example embodiments, unless otherwise limited by the claims.

### (Configuration of Plasma Processing Apparatus)

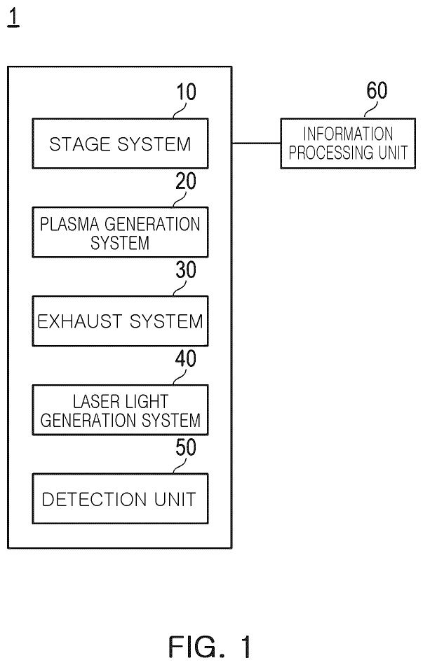

FIG. 1 illustrates a configuration of a plasma processing apparatus 1 according to some example embodiments of the inventive concepts. The plasma processing apparatus 1 may include, for example, a stage system 10, a plasma generation system 20, an exhaust system 30, a laser light generation unit 40, a detection unit 50, and an information processing unit 60. Each of the stage system 10, the plasma generation system 20, the exhaust system 30, the laser light generation unit 40, and the detection unit 50, and the information processing unit 60 may be connected via a network, for example.

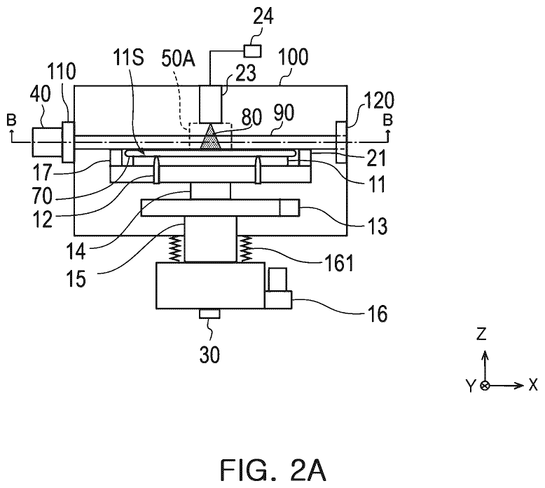

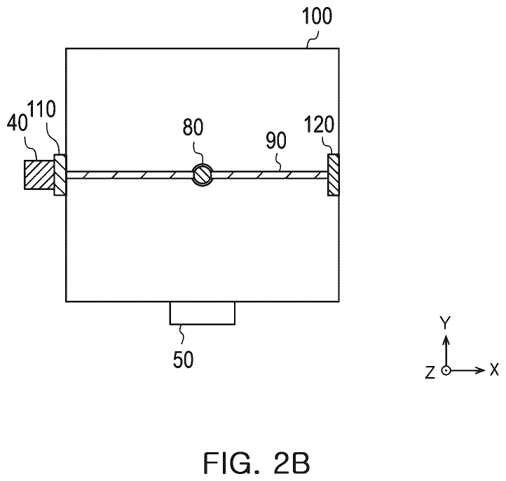

FIGS. 2A and 2B illustrate a configuration of a chamber 100 in which plasma processing is performed, according to some example embodiments. FIG. 2A illustrates a configuration of a front surface of the chamber 100, according to some example embodiments, and FIG. 2B illustrates a cross-sectional configuration taken along line B-B of FIG. 2A, according to some example embodiments.

The chamber 100 may be or provide a working region or space for performing plasma processing on a substrate 70. Within the chamber 100, a reduced pressure state may be formed by exhausting air through the exhaust system 30. The substrate 70 may be, for example, a silicon (Si) substrate. A size of the substrate 70 may be, for example, 12 inches. Within the chamber 100, for example, local etching treatment may be performed on the substrate 70 using an active species 80. In the chamber 100, for example, a view port 110 may be provided for observing the inside of the chamber 100 from the outside of the chamber 100. Within the chamber 100, various sensors such as a pressure sensor, or the like, may be provided. In the following description, with regards to movement directions of the substrate 70 within the chamber 100, a moving direction parallel to a main surface of the substrate 70 may be referred to as an X-direction and a Y-direction, and a moving direction orthogonal to the main surface of the substrate 70 may be referred to as a Z-direction.

The stage system 10 may have, in addition to the fixing or securing the substrate 70, a heating and cooling function, a bias application function, a rotation function, a lifting function, a discharge blocking function, and the like, to the substrate 70. The stage system 10 may include, for example, a stage 11, a lift pin 12, a driving unit in an X-direction 13, a driving unit in a Y-direction 14, a rotation driving unit 15, and a driving unit in a Z-direction 16. The stage 11 provided within the chamber 100 may include a mounting surface 11S (or upper surface). A substrate 70 may be mounted on the mounting surface 11S, and plasma processing may be performed thereon. The mounting surface 11S may be in or parallel to an X-Y plane.

The stage 11 may be provided with, for example, an electrostatic chuck, a heating circuit, and a cooling circuit. The electrostatic chuck adsorbs or secures the substrate 70 to the stage 11. The heating circuit and cooling circuit may heat and cool the substrate 70. The stage 11 may be provided with a mechanism for introducing a rare gas such as argon or helium to a back (or lower) side of the substrate 70, and exhausting the rare gas. By this rare gas, temperature transfer between the mounting surface 11S and the substrate 70 may be increased, improved, or optimized. In addition, a temperature sensor, or the like for detecting a temperature of the substrate 70 may be provided on the stage 11. In addition, the stage 11 may be configured to control a progress of an active species 80 in the direction of the substrate 70 to inhibit or minimize contact of the active species 80 with the substrate, and for example, a lower electrode may be provided on the stage 11. In addition, an edge ring 17 may be provided on the stage 11. The edge ring 17 may be positioned around the substrate 70 for confining plasma to a volume above the substrate 70 and/or to protect the electrostatic chuck, the heating circuit, the cooling circuit, and other components from erosion by the plasma. The stage 11 may have a temperature adjustment function, a position raising/lowering function, and a bias application function of the edge ring 17.

The stage 11 may include multiple lift pins 12 (two shown) that are evenly distributed (e.g., equally spaced from each other) to evenly support the substrate 70. The plurality of lift pins 12 may be configured to be movable in the Z-direction. The substrate 70 may be supported by a tip of the lift pin 12, protruding from the mounting surface 11S. By moving the tip of each lift pin 12 such that the tip is in the same plane as the mounting surface 11S or moving each lift pin 12 to be inside of the stage 11 such that the tip of each lift pin 12 is below the plane of the mounting surface 11S, the substrate 70 may be mounted on the mounting surface 11S.

The driving unit in the X-direction 13, the driving unit in the Y-direction 14, and the driving unit in the Z-direction 16 may drive the mounting surface 11S of the stage 11 in the X-direction, Y-direction, and Z-direction, respectively. The driving unit in the Z-direction 16 may include a bellows structure 161, and may be configured to be elevatable (e.g., extend vertically upward) and contractable (e.g., retract vertically downward) under reduced pressure. The rotation driving unit 15 may rotate the mounting surface 11S of the stage 11 clockwise or counterclockwise within the X-Y plane. The rotation driving unit 15 may have a heating circuit, a cooling circuit, a power supply function to secure the substrate 70 using the electrostatic chuck, a bias application circuit, or a sensor function. For example, the rotation driving unit 15 includes a slip ring, and a magnetic fluid seal, a magnetic coupling, or the like, and may be used as a seal between atmospheric pressure and reduced pressure environments. The rotation driving unit 15 may include an encoder (e.g., a rotary encoder) for controlling an amount of rotation of the stage 11.

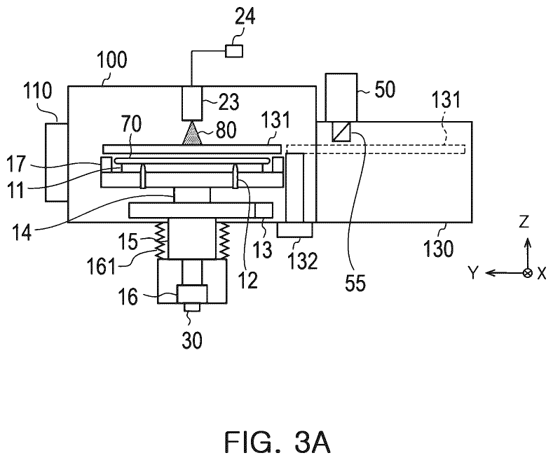

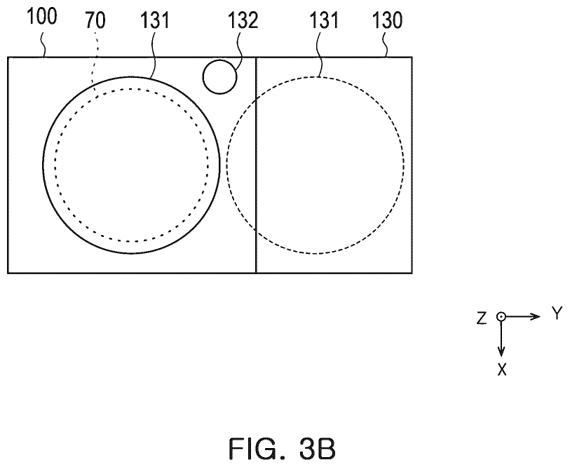

The plasma processing apparatus 1 may include a configuration for protecting the substrate 70 disposed on the stage 11 from the active species 80. The plasma processing apparatus 1 may include, for example, a shutter (the shutter 131 of FIG. 3A and FIG. 3B described below).

FIGS. 3A and 3B illustrate a configuration of a shutter 131 used in the plasma processing apparatus 1, according to some example embodiments. The shutter 131 may be switchable between a closed state and an open state. Solid lines in FIGS. 3A and 3B represent a shutter 131 in a closed state, and dashed lines in FIGS. 3A and 3B represent a shutter 131 in an open state. A surface of the shutter 131 may be coated or treated with a film to reduce or minimize etching thereof by plasma. Additionally or alternatively, the surface of the shutter 131 may be made rough (e.g., have a desired surface roughness). In addition, the shutter 131 may have a heating circuit, a cooling circuit, a bias control circuit, and the like, embedded therein, and these circuits may be configured to change a duty ratio by multi-pulse.

The shutter 131 in the closed state may be disposed to be spaced apart from a mounting surface 11S of the stage 11 in a Z-direction, to face the stage 11 of the mounting surface 11S, and may cover (e.g., entirely) the mounting surface 11S. An area of an X-Y plane of the shutter 131 (e.g., a cross-sectional area of the shutter 131 in the X-Y plane) may be larger than an area of the mounting surface 11S, for example. When the shutter 131 is in the closed state, the shutter 131 may protect the mounting surface 11S and/or the substrate 70 mounted on the mounting surface 11S from the active species 80.

The shutter 131 in the open state is positioned laterally offset (Y-direction) from the mounting surface 11S of the stage 11, and may expose the mounting surface 11S and/or the substrate 70. For example, an as illustrated, the shutter 131 may be moved to a side of the substrate 70 to expose the mounting surface 11S and/or the substrate 70.

The shutter 131 in the open state may be accommodated in, for example, a shutter room 130. The shutter room 130 may be a space or volume provided adjacent to the chamber 100 in the Y-direction, for example.

The closed and open states of the shutter 131 may be switched, for example, by a shutter driving unit 132. The shutter driving unit 132 may rotate the shutter 131 by, for example, supporting one end of the shutter 131 in the Y-direction. Accordingly, the closed and open states of the shutter 131 may be switched. The shutter driving unit 132 may be, for example, disposed external to the chamber 100. The interior and exterior of the chamber 100 may be isolated, for example, by interposing a magnetic fluid seal or a magnetic coupling. The shutter driving unit 132 may have an encoder function for detecting and/or controlling the amount of rotation to a predetermined or desired angular position.

The plasma generation system 20 may have a gas supply function to the supply gas to the chamber 100, a gas mixing function, a gas heating and cooling function, and/or a voltage application function to the gas. Referring to FIG. 2A, the plasma generation system 20 may include a nozzle 23 and a gas supply unit 24. For example, the nozzle 23 may function as, or otherwise include, an upper electrode. The upper electrode may have, for example, a surface discharge structure integrated with the nozzle 23. A lower electrode provided on the stage 11 and an upper electrode integrated with the nozzle 23 may, for example, face each other in the Z-direction. The upper electrode may be disposed to be spaced apart from the nozzle 23 on the gas supply line. In this case, the upper electrode may have an electrode structure in the form of an external induction coil, for example. The plasma generation system 20 may generate plasma, for example, in the form of remote plasma. In the form of remote plasma, plasma is generated in a position sufficiently spaced apart from the substrate 70, for example, in a position between the nozzle 23 and the gas supply unit 24.

The nozzle 23 provided within the chamber 100 may emit gas supplied from the gas supply unit 24 toward the substrate 70. When gas is emitted from the nozzle 23 while a predetermined voltage is applied between the lower electrode and the upper electrode, the gas may be converted into plasma and an active species 80 may be generated. Using these active species 80, plasma processing may be performed on the substrate 70 disposed on the stage 11. The gas emitted from the nozzle 23 may include an active species raw material. The nozzle 23 may be disposed, for example, to face the stage 11 in the Z-direction. The nozzle 23 is an example of an active species emitting unit that may be used in some example embodiments. However, example embodiments are not limited thereto, and other types of active species discharge units may also be used based on application and/or design.

A gas supplied from the gas supply unit 24 to the nozzle 23 may be or include a perfluorocarbon (PFC) gas. Perfluorocarbon may refer to a CxFy group of gases, and examples of the CxFy gases may include carbon tetrafluoride (CF4), and the like. The gas supplied from the gas supply unit 24 to the nozzle 23 may be or include a hydrofluorocarbon (HFC) gas such as trifluoromethane (CHF3), a chlorofluorocarbon (CFC) gas such as trichlorofluoromethane (CCl3F), or the like. However, gases other than the gases described above may be supplied from the gas supply unit 24 to the nozzle 23, and the other gases may be or include, for example, a fluorocarbon gas, a hydrocarbon-based gas, an organic halogen gas not containing F, an inorganic halogen gas, and the like. As an example, and in-organic halogen gas may be or include sulfur hexafluoride (SF6). In some example embodiments, the gas supplied from the gas supply unit 24 to the nozzle 23 may be or include nitrogen trifluoride (NF3), hydrogen (H), xenon (Xe), argon (Ar), helium (He), a precursor gas or a mixed gas.

The exhaust system 30 may exhaust process gas from the chamber 100 and cleaning gas from the chamber 100 after a cleaning operation, and control a pressure within the chamber 100 by controlling the amount of gas (process gas and/or cleaning gas) in the chamber 100. The exhaust system 30 may include, for example, a pump, or the like. By this exhaust system 30, the gas within the chamber 100 is exhausted. The exhaust system 30 may additionally include an anti-corrosion film, a heating and cooling system, or the like. The exhaust system 30 may be fluidly coupled to the chamber 100 via a view port 110 or a lower portion of the stage 11 (as illustrated).

The laser light generation unit 40 may generate a sheet-shaped laser light, i.e., a laser sheet 90, in an observation region 50A of the plasma processing apparatus 1. The observation region 50A may include at least a portion of region between the mounting surface 11S and the nozzle 23. In the observation region 50A, an active species 80 may exist. The laser light generation unit 40 may form a laser sheet 90 in the observation region 50A, such that planar excited luminescence of an atom can be achieved, for example, in a bulk plasma region or a sheath plasma region. As described above, the plasma processing apparatus 1 may quantify an absolute ion density, electron temperature, or the like, as a state of the active species 80 by using a laser-induced fluorescence method, for example. The laser light generation unit 40 may be disposed, for example, in a position adjacent to the chamber 100 in the X-direction. The main surface of the laser sheet 90 may be, for example, a surface perpendicular to the mounting surface 11S, and may be in the X-Z plane. In some example embodiments, a width (a size in the Z-direction) of the laser sheet 90 may be 50 mm (or about 50 mm) or less. In some example embodiments, a width (a size in the Z-direction) of the laser sheet 90 may be 1 mm (or about 1 mm) or less.

A main surface of the laser sheet 90 may be formed in a direction intersecting a mounting surface 11S or a substrate 70. In some example embodiments, in order to suppress or reduce or minimize scattered light, laser damage, or the like, caused by the laser sheet 90, an end (an end in a Z-direction) of the laser sheet 90 may be spaced apart from the surface of the mounting surface 11S or the substrate 70. The laser sheet 90 may be dispersed or moved, and a portion thereof may be used for trimming an edge region of the substrate 70. In some example embodiments, excited luminescence may be generated by the generated by-products and the laser sheet 90. The plasma processing apparatus 1 may detect the excited luminescence, and may provide feedback on processing information. In some example embodiments, it is desirable that the plasma processing apparatus 1 trims the substrate 70 while rotating the stage 11.

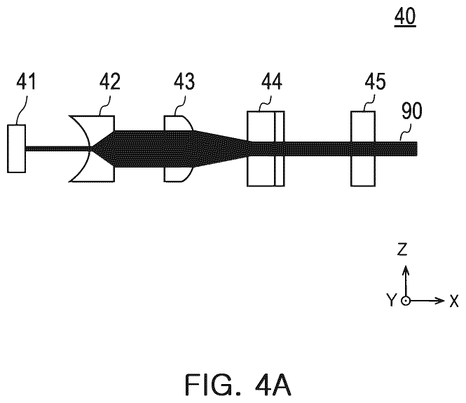

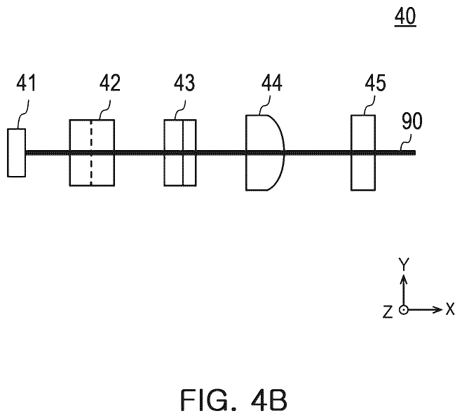

FIGS. 4A and 4B illustrate an example configuration of a laser light generation unit 40, according to some example embodiments. The laser light generation unit 40 may include, for example, a light source 41, a diffusion lens 42, a converging lens in a Z-axis direction 43, a converging lens in an X-direction 44, and a focus lens 45. Here, the diffusion lens 42, the converging lens in the Z-axis direction 43, the converging lens in the X-direction 44, and the focus lens 45 may correspond to one example of a lens unit, and example embodiments are not limited thereto. An anti-reflection film may be formed on the lens surfaces of the diffusion lens 42, the converging lens in the Z-axis direction 43, the converging lens in the X-direction 44, and the focus lens 45.

The light source 41 may emit pulsed laser light in a form of a beam. A wavelength of the laser light emitted by the light source 41 may be, for example, a vacuum ultraviolet range (10 nm) to an infrared range (2500 nm). For example, the wavelength of the laser light emitted by the light source 41 may be varied within this wavelength range. Accordingly, an emission spectrum in the observation region 50A may be measured. In some example embodiments, the light source 41 may include a dye laser and may be configured to change the wavelength in units of 0.001 nm or less using the dye laser.

The diffusion lens 42 and the converging lens in the Z-axis direction 43 may be or include, for example, a cylindrical lens. A laser sheet 90 may be formed by the laser light in the form of a beam emitted from a light source 41 by passing through the diffusion lens 42, the converging lens in the Z-axis direction 43, the converging lens in the X-direction 44, and the focus lens 45. The laser sheet 90 formed in the laser light generation unit 40 may be introduced into a chamber 100 through, for example, a view port 110. An anti-reflection film or a film having etching resistance may be formed on a surface of the view port 110. The chamber 100 may be provided with an exit-side view port from which laser light is emitted. This exit-side view port may be disposed, for example, opposite the view port 110. A line connecting the two view ports may be arranged at an angle with the mounting surface 11S. Accordingly, light diffusion may be reduced or minimized. The laser light generation unit 40 may include an oscillator, or the like.

For example, a damper 120 may be disposed on an inner wall of the chamber 100. The damper 120 may protect the chamber 100 from the laser sheet 90. The damper 120 may reduce or minimize damage to internal components and may reduce or minimize light scattering within the chamber 100. The damper 120 may be provided in a position corresponding to the end of the laser sheet 90 within the chamber 100. The damper 120 may be disposed, for example, in the X-direction, opposite the view port 110. The damper 120 may also be disposed outside of the chamber 100. The damper 120 may have a cooling function corresponding to high-line laser energy. A surface of the damper 120 may have a desired roughness. The damper 120 may have a black body structure, and may effectively minimize or reduce light scattering.

The detection unit 50 may detect excited luminescence which is generated in the observation region 50A. The detection unit 50 may be configured to detect and/or measure, for example, a quenching time period of the excited luminescence of light metal atoms. In some example embodiments, the quenching time period may be 1 nanosecond (or about 1 nanosecond) or more and 20 nanoseconds (or about 20 nanoseconds) or less. The detection unit 50 may detect excited luminescence with a quenching time period of less than 1 nanosecond using, for example, a gating configuration (shutter time). The quenching time period may be the time from when a target is excited to when the target is quenched. This excited luminescence may be generated by, for example, an active species 80 excited by a laser sheet 90. The plasma processing apparatus 1 including the detection unit 50, according to some example embodiment, may detect the state of the active species 80 around the stage 11 and adjust the plasma processing conditions. The detection unit 50 may detect the excited luminescence over time, for example. The detection unit 50 may be disposed, for example, in a position facing the main surface of the laser sheet 90. The detection unit 50 may be disposed, for example, outside the chamber 100. The detection unit 50 may detect by-products (e.g., silicon (Si), oxygen, and nitrogen) with a short quenching time period obtained from the substrate 70, and may sequentially reflect changes in processing recipes.

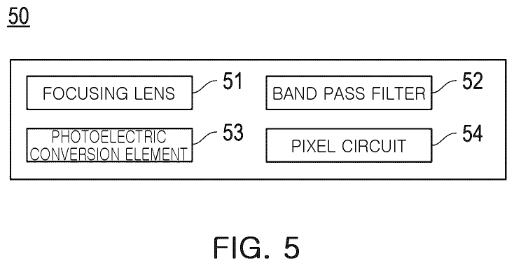

FIG. 5 illustrates a configuration of a detection unit 50, according to some example embodiments. The detection unit 50 may be or include an imaging device capable of imaging light having a wavelength in an extreme ultraviolet range (1 nm to 10 nm) to an infrared range (2500 nm), and may include an Intensified Charge Coupled Device (ICCD). The detection unit 50 may include, for example, a focusing lens 51, a band pass filter 52, a photoelectric conversion element 53, and/or a pixel circuit 54.

The focusing lens 51 may focus light from the observation region 50A onto a band pass filter 52. The band pass filter 52 may selectively transmit light in a predetermined wavelength range. Light passing through the band pass filter 52 may be incident on the photoelectric conversion element 53. The photoelectric conversion element 53 may convert the incident light into an electric signal. The photoelectric conversion element 53 may or include, for example, a single-photon avalanche diode (SPAD). The photoelectric conversion element 53 including a SPAD may provide a photomultiplier function to the detection unit 50, or alternatively may configure the detection unit 50 to include a photomultiplier function. Accordingly, the detection unit 50 may detect excited luminescence having a relatively shorter time duration and/or excited luminescence that may be relatively weaker with relatively higher precision. The pixel circuit 54 may detect the electric signal generated by the photoelectric conversion element 53 for each pixel, and generate luminescence information. The luminescence information may be information regarding the excited luminescence generated at a predetermined point in time, and may include, for example, information regarding the wavelength and intensity of the excited luminescence. The luminescence information generated by the pixel circuit 54 may be transmitted to the information processing unit 60.

The detection unit 50 may have a band stop configuration. The band stop configuration may filter the laser light wavelength by selectively passing a luminescence wavelength at which atoms return to a ground state. The band stop configuration can be implemented by, for example, a notch filter, a dichroic mirror, and the like. The detection unit 50 may have, for example, a delay compensation function.

Using this delay compensation function, the delay from laser oscillation to luminescence can be compensated. In some example embodiments, the detection unit 50 function as a delay pulse generator. A shutter of the detection unit 50 may be opened and closed, for example, as discussed below. When a voltage between a photoelectric surface of the photoelectric conversion element 53 and a multi-channel plate is negative, photoelectrons may be accelerated toward a multi-channel surface, and the shutter may be opened. When photoelectrons are accumulated on the photoelectric surface the shutter may be closed. The shutter time (gating width) may be 2 ns (or about 2 ns) or less.

The information processing unit 60 may be configured to interpolate the measurement information in advance as a processing recipe. The information processing unit 60 may be, for example, a Personal Computer (PC), or the like. The information processing unit 60 may quantify a state of an active species 80 based on the luminescence information generated by the detection unit 50. The state of the active species 80 may be, for example, the state of the ion density, the state of the electron temperature, and the like. The information processing unit 60 may then convert the state of the quantified active species 80 into a physical quantity, and provide a variable processing amount to the stage system 10, the plasma generation system 20, the exhaust system 30, and the like. The information processing unit 60 may be configured to obtain and/or measure different parameters of the substrate 70 (e.g., thickness, resistivity, and the like), obtain and/or measure parameters during processing of the substrate 70 (e.g., the thickness of a film formed on the substrate, the amount of etching performed on the substrate 70), and receive control signals/commands from an external device (e.g., an external controller) to control the plasma processing.

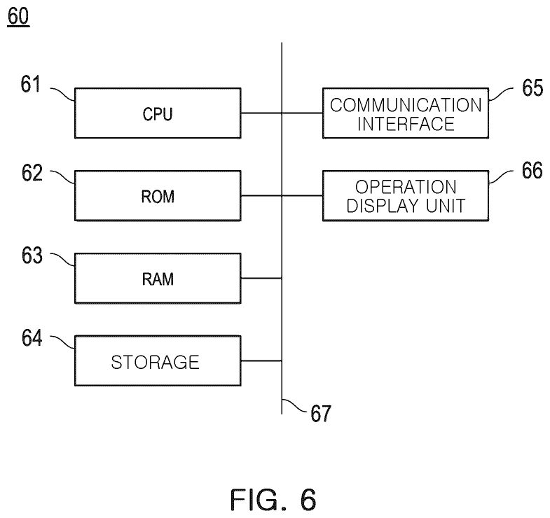

FIG. 6 is a block diagram illustrating an information processing unit 60, according to some example embodiments. The information processing unit 60 may include, for example, a Central Processing Unit (CPU) 61, a Read Only Memory (ROM) 62, a Random Access Memory (RAM) 63, a storage 64, a communication interface 65, and an operation display unit 66. Each component may be connected to each other so as to be able to communicate with each other with a bus 67. The information processing unit 60 may also include a Graphics Processing Unit (GPU). the GPU may configure the information processing unit 60 to perform high speed/frequency calculations on training data, image data, and large-scale data processing layers for decision-making for the purpose of machine learning. The information processing unit 60 may also estimate the state of the active species 80 using a machine learning model.

The machine learning model may be stored in a Manufacturing Execution System (MES) manufacturing execution system provided in a host computer, and decision-making information may be provided to a device group at a desired time internals using a desired communication protocol from an information layer from each device group, an interpretation layer based on the machine learning model, or the like. Alternatively or additionally, it may be beneficial to include a configuration in which an edge computing layer (information layer/interpretation layer) that may make decisions at high speed without interposing an upper host computer is attached to the information processing unit 60, and a bus 67 is interposed to execute manufacturing in real time through the process.

The CPU 61 may perform control of each of the components or various operation processing according to the program recorded in the ROM 62 and storage 64. Example functions of the CPU 61 will be described later.

The ROM 62 may store various programs or information.

The RAM 63 may temporarily store programs or information as a working region.

The storage 64 may store various programs including an operating system or various information.

The communication interface 65 may be an interface for communicating with other devices. As the communication interface 65 may be configured to operate according to various, desired wireless or wired communication standards. The communication interface 65 may be used, for example, when receiving luminescence information from the detection unit 50 and/or transmitting processing conditions to the plasma generation system 20.

The operation display unit 66 may be configured by a display unit such as a Liquid Crystal Display (LCD), an organic EL display, or the like, and a touch panel including a touch sensor, for example. A display unit that may display various information and an operating unit receiving various operations from a user may also be included as the operation display unit 66. The display unit may be configured by a viewer software or a printer, in addition to the display, and the operating unit may be configured by a pointing device such as a touch sensor and a mouse, a keyboard, or the like.

### (Function of Information Processing Unit)

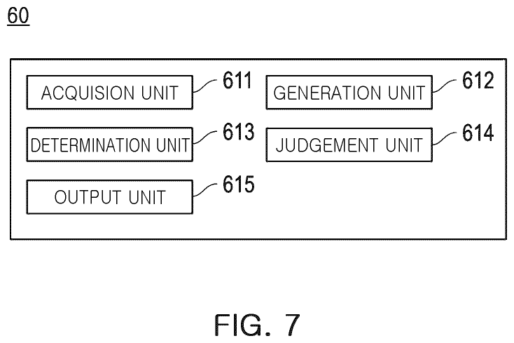

FIG. 7 is a block diagram illustrating a functional configuration of an information processing unit 60. The information processing unit 60 may be configured to function as an acquisition unit 611, a generation unit 612, a determination unit 613, a judgment unit 614, and an output unit 615 by having the CPU 61 read and executing a computer-readable program code stored in the storage 64.

The acquisition unit 611 may acquire luminescence information regarding the excited luminescence detected by the detection unit 50. The luminescence information may be binary processed, quaternary processed, or the like, through image processing.

The acquisition unit 611 may, for example, acquire luminescence information regarding the excited luminescence detected by the detection unit 50 at each of a plurality of point in times. The acquisition unit 611 may, for example, acquire first luminescence information and second luminescence information. The first luminescence information may be information regarding the excited luminescence detected by the detection unit 50 at a first point in time. The second luminescence information may be information regarding the excited luminescence detected by the detection unit 50 at a second point in time, later than the first point in time. The first point in time may be, for example, a point in time before a start of plasma processing on the substrate 70, and the second point in time may be, for example, a point in time after the start of plasma processing on the substrate 70.

The generation unit 612 may generate active species information regarding the state of the active species 80 around or adjacent or proximate the stage 11, based on the luminescence information acquired by the acquisition unit 611. The active species information may include, for example, information regarding a luminescence spectrum of gas molecules, atoms, and radicals included in the active species 80. The active species information may include information regarding at least one of the density distribution and momentum of gas molecules, atoms, and radicals included in the active species 80. The active species information may include information regarding at least one of the temperature, density, and velocity components of electrons included in the active species 80. The generation unit 612 may generate, for example, first active species information regarding the state of the active species 80 at the first point in time, based on the first luminescence information, and second active species information regarding the state of the active species 80 at the second point in time, based on the second luminescence information. The active species information may include information regarding the spatiotemporal distribution of the state of the active species 80.

The determination unit 613 may decide conditions of plasma processing based on the active species information generated by the generation unit 612. The conditions of plasma processing may be referred to as a recipe for plasma processing. The conditions of plasma processing may be, for example, conditions such as a flow rate of gas supplied from a nozzle 23, a ratio of gas, a modulation pulse of a lower electrode and an upper electrode, a height of the nozzle 23, an exhaust amount by the exhaust system 30, a transport speed of the stage 11, and the like. The determination unit 613 may determine a first condition of plasma processing at the start of processing based on, for example, the first active species information.

The judgment unit 614 may determine whether to change the conditions of plasma processing based on the active species information generated by the generation unit 612. The judgment unit 614 may determine whether to change a first condition of plasma processing based on, for example, the second active species information. The judgment unit 614 may determine whether to change the first condition by comparing the second active species information with reference information, for example. The judgment unit 614 may determine to change the first condition, for example, when the density distribution of gas molecules, or the like, included in the active species 80 is outside the range of the reference density distribution. When an absolute amount of gas molecules, or the like, included in the active species 80 is outside of the range of a reference amount, the judgment unit 614 may determine that the first condition is changed. The judgment unit 614 may determine whether to change the first condition by comparing the second active species information with the first active species information.

When it is determined that the judgment unit 614 changes the first condition, the determination unit 613 may determine a second condition, which is different from the first condition of plasma processing. The second condition may be, for example, a condition such as a flow rate of gas supplied from a nozzle 23, a ratio of gas, a modulation pulse of a lower electrode and an upper electrode, a height of the nozzle 23, an exhaust amount by an exhaust system 30, a transport speed of the stage 11, and the like. The determination unit 613 may determine a second condition based on third active species information regarding the state of the active species 80 at a third point in time, later than the second point in time, for example. The determination unit 613 may also determine the second condition of plasma processing based on the second active species information.

The output unit 615 may output information regarding conditions of plasma processing determined by the determination unit 613. The output unit 615 may output information regarding the conditions of plasma processing to, for example, an operation display unit 66. Accordingly, various conditions of plasma processing may be displayed on the operation display unit 66. The output unit 615 may also output information regarding the conditions of plasma processing to the stage system 10, the plasma generation system 20, the exhaust system 30, and the like. Accordingly, for example, each portion of the plasma processing apparatus 1 may be adjusted to follow the first condition or the second condition. The output unit 615 may also output information regarding the judgment result by the judgment unit 614.

Any or all of the elements described with reference to FIGS. 1, 5, and 7 may communicate with any or all other elements described with reference to FIGS. 1, 5, and 7. For example, any element may engage in one-way and/or two-way and/or broadcast communication with any or all other elements in any of the figures, to transfer and/or exchange and/or receive information such as but not limited to data and/or commands, such as in a serial and/or parallel manner, via a bus such as a wireless and/or a wired bus. The information may be in encoded various formats, such as in an analog format and/or in a digital format, without being limited thereto.

### (Processing Overview of Information Processing Unit)

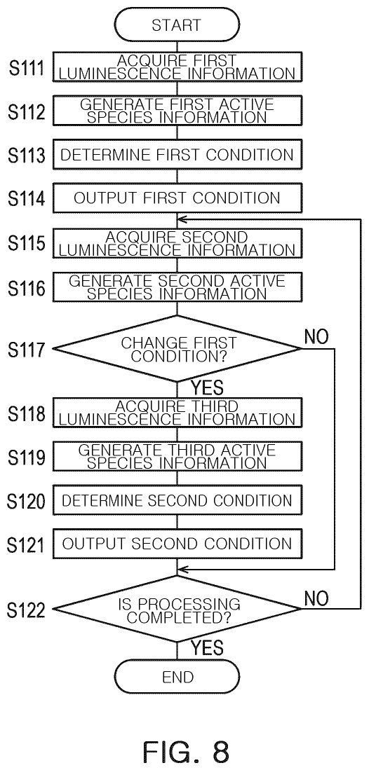

FIG. 8 is a flowchart of a method of operating the plasma processing apparatus 1, according to some example embodiments. The method may be performed using or based on the control received from the information processing unit 60. It is understood that additional operations can be provided before, during, and after the operations in FIG. 8, and some of the operations described below can be replaced or eliminated, for additional embodiments of the method. The order of the operations/processes may be interchangeable, or two or more operations can be performed simultaneously.

The information processing unit 60 may perform the method in FIG. 8 based on execution of a computer readable program code stored in the storage 64. The computer readable program code may be executed by a CPU 61 controlling each unit of the information processing unit 60. In addition or alternatively, the information processing unit 60 may receive an execution command value or information through a communication interface 65 from a hierarchically higher host computer or other controlling device that may command and/or control information processing unit 60 to perform the method.

The information processing unit 60 may acquire first excited luminescence information (operation S111). At a first point in time, a substrate 70 may be mounted on a mounting surface 11S of a stage 11, and the substrate 70 may be secured on the stage 11, for instance, via an electrostatic force. After the substrate 70 is secured on the stage 11, a heat transfer gas (e.g., He or Ar) may be supplied between a back surface of the substrate 70 and the mounting surface 11S, and the substrate 70 may be heated or cooled as needed. In this case, the shutter 131 may be in a closed state (a state in which the shutter 131 is moved from a shutter room 130 to the mounting surface 11S). In this state, the plasma generation system 20 may emit gas (or active species 80, being converted into plasma from the nozzle 23, and the laser light generation unit 40 may generate a laser sheet 90. By detecting the excited luminescence generated in the observation region 50A at this first time, the detection unit 50 may generate first luminescence information.

Next, the information processing unit 60 may generate first active species information based on the first luminescence information acquired in operation S111 (operation S112). Here, the information processing unit 60 may process luminescence information regarding the excited luminescence of various active species 80 by performing binary processing, quaternization processing, or the like, to generate information regarding luminescence density distribution per unit cross-sectional area or unit volume, per unit time, or the like. The information processing unit 60 may determine a first condition of plasma processing by each coefficient amount (gas flow rate, pulse duty ratio, chamber pressure, or the like) calculated from a physical quantity based on the first active species information generated in operation S112 (operation S113). Thereafter, the information processing unit 60 may output the first condition determined in operation S113 (operation S114).

After the plasma processing apparatus 1 initiates plasma processing under the first condition, the information processing unit 60 may acquire second luminescence information (operation S115). In other words, at the second time, the plasma processing apparatus may perform plasma equivalent processing on the shutter 131 under the first condition.

Next, the information processing unit 60 may generate second active species information based on the second luminescence information acquired in operation S115 (operation S116). The information processing unit 60 may determine whether to change the first condition of plasma processing based on the second active species information generated in operation S116 (operation S117).

Here, in operation S117, the information processing unit 60 may make a judgment as to whether a desired amount of threshold for target processing is satisfied. When it is determined that the threshold is satisfied and the first condition is passed (operation S117: NO), the information processing unit 60 may proceed with the processing of operation S122. When the judgment result is determined to be passed, the shutter 131 may be switched from a closed state to an open state (the shutter 131 moves to the shutter room 130). Then, the mounting surface 11S of the stage 11 can be moved in the Z-direction (process position) to get closer to the nozzle 23.

When it is determined that the threshold is not satisfied and the information processing unit 60 changes a first condition (mismatched) (operation S117: YES), the information processing unit 60 may acquire third luminescence information and generate third active species information (operations S118, S119). The third luminescence information may be information regarding the excited luminescence detected at a third point in time, later than the second point in time. Thereafter, the information processing unit 60 may determine and output a second condition of plasma processing based on the third active species information generated in operation S119 (operation S120, S121). In some example embodiments, when operation S117 is YES, the information processing unit 60 may regenerate luminescence information and active species information in operations S118 and S119, and change each coefficient amount (gas flow rate, pulse duty ratio, chamber pressure, or the like) in operation S120. Accordingly, the stage system 10, the plasma generation system 20, and the exhaust system 30 may be adjusted to the second condition. The plasma processing apparatus 1 may perform plasma processing on the substrate 70 by changing from the first condition to the second condition.

The plasma processing apparatus 1 may drive the stage 11 along the X-direction, Y-direction, Z-direction or R-axis based on (or in accordance with) the second condition output in operation S121. The plasma processing apparatus 1 may drive the stage 11 along the X-direction, Y-direction, Z-direction or R-axis based on the second condition output in operation S121. In this case, the plasma processing apparatus 1 may adjust a relative speed and relative distance of the stage 11 with respect to the nozzle 23, while considering a path and height of the stage 11, which are calculated and predicted in advance based on the desired amount (preliminary measurement value) such as a thickness, opening amount, and the like, of the substrate 70. The information processing unit 60 may determine whether to end processing after outputting the second condition (operation S122). When it is determined not to end processing (operation S122: NO), the information processing unit 60 may return to the processing of operation S115.

When it is determined to end processing (operation S122: YES), the information processing unit 60 may end processing.

The plasma processing apparatus 1 may be configured to enable constant detection of luminescence information during the plasma processing process. The plasma processing apparatus 1 may, for example, maintain the shutter 131 in a closed state when changing processing conditions (for example, when transitioning from operation S117 to operation S118). Alternatively, if the threshold change is allowed, the shutter 131 may be in an open state. The plasma processing apparatus 1 may be configured to adjust the threshold values to one or more desired values at which the processing may be stopped.

### (Technical Effect of Plasma Processing Apparatus)

The plasma processing apparatus 1, according to some example embodiments, may include a detection unit 50, and excited luminescence generated in the observation region 50A may be detected by the detection unit 50. Accordingly, a state of an active species 80 around or adjacent or in the vicinity of the stage 11 may be identified using the excited luminescence, and plasma processing conditions can be adjusted in a relatively shorter duration of time.

In plasma processing such as etching, or the like, even if processing of the substrate is initiated under appropriate and/or desired conditions, there may be conditions generated in which sufficient or desired processing precision may not be maintained. This may be because the conditions or environment inside the chamber 100 may change over time due to wear of a nozzle, deposition of by-products inside and/or on the nozzle, atmospheric leaks, and the like. In addition, appropriate and/or desired processing conditions may differ for each apparatus due to component tolerances and mounting or construction deviations.

In this regard, in the plasma processing apparatus 1, the state of the active species 80 (e.g., absolute density) may be monitored in real time by the detection unit 50. Therefore, even if the state of the active species 80 changes or deviates (e.g., beyond a desired threshold value) from a state at the start of processing, for example, due to deterioration (e.g., wear and tear) of the nozzle 23, or the like, the plasma processing conditions may be adjusted according to the change in the state of the active species 80. Therefore, it may be possible to improve and/or optimize the processing precision of the substrate 70.

As described above, in the plasma processing apparatus 1, according to some example embodiments, the detection unit 50 may detect excited luminescence.

Accordingly, the state of the active species 80 around, adjacent or in a vicinity of the stage 11 may be identified using the excited luminescence, and the plasma processing conditions can be adjusted. Therefore, it may be possible to improve the processing precision.

For example, detection unit 50 may be configured to measure distributions such as atomic density, ion density, electron temperature, or electron density from a center of the stage 11 (or, alternatively, from a center of the substrate 70) to a radially outer edge of the stage 11 (or, alternatively, to a radially outer circumference of the substrate 70). For example, in some example embodiments, the active species 80 can be captured using a density distribution as discussed below. Generally, there is relatively smaller or reduced bias in the density distribution of the active species 80 on a processing surface of the substrate 70. The etching, injection, and film deposition amounts for the substrate 70 can be controlled in real-time by making the density distribution of the active species 80 uneven or by increasing or decreasing the overall density. One of the density adjustment mechanisms (for instance, density adjustment knobs) used to adjust the density of the active species 80 may include a pressure controller for the exhaust valve. For example, in the plasma processing apparatus, the density distribution of the active species 80 can be varied through a confinement ring positioned on the outer periphery of the substrate 70, with variable control being performed by measuring the actual density in real-time. Using the method according to example embodiments above, the deviation from the target value can be controlled by measuring (e.g., constantly or at desired time intervals) the density distribution of the active species 80 in a space above the stage 11 (e.g., directly above the substrate 70). There are various other mechanisms (e.g., knobs) that control the state of the active species 80, such as the actual stage temperature, gas flow rate, bias voltage, and modulation field (duty ratio). By adjusting the knob related to the number of electron collisions, diffusion speed, diffusion angle, or density distribution of the active species 80, various profiles such as etching or injection amounts for the substrate 70 can be controlled.

For example, in a CMOS Image Sensor (CIS) for mobile devices, it may be beneficial to include an improved in-plane uniformity on the substrate due to miniaturization of a pixel size, a lamination process, and the like. Therefore, the plasma processing apparatus 1, according to some example embodiments, may be suitably used for manufacturing the CIS for mobile devices.

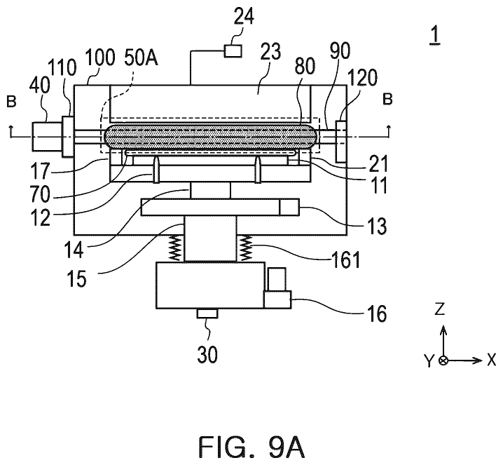

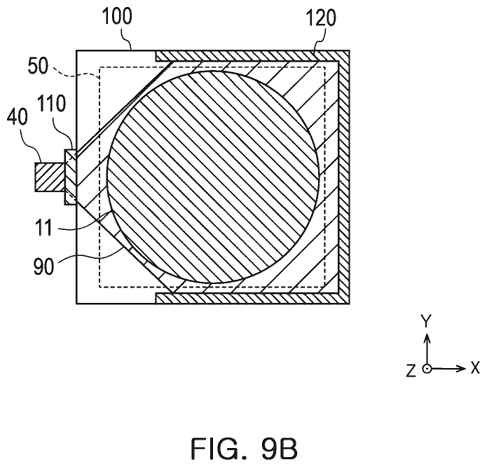

FIGS. 9A and 9B illustrate a configuration of a plasma processing apparatus 1, according to some example embodiments. The plasma processing apparatus 1 may be same as or similar in some respects to the plasma processing apparatus 1 of FIG. 1, and therefore may be best understood with reference thereto where like numerals indicate like elements not described again in detail. FIG. 9A illustrates an example of the configuration of a front surface of a chamber 100, and FIG. 9B illustrates an example of a cross-sectional configuration along the line B-B illustrated in FIG. 9A. FIG. 9A may be the same as or similar in some respects to FIG. 2A described above according to some example embodiments, and FIG. 9B may be the same as or similar in some respects to FIG. 2B described above according to some example embodiments. In the plasma processing apparatus 1 in FIG. 9A, the laser light generation unit 40 may form a laser sheet 90 having a main surface parallel to the mounting surface 11S.

The main surface of the laser sheet 90 may be, for example, an X-Y plane. The detection unit 50 may be disposed, for example, in a position facing the main surface of the laser sheet 90. The detection unit 50 may be disposed, for example, between the mounting surface 11S of the stage 11 and the nozzle 23. The detection unit 50 may be disposed, for example, in a position facing the laser sheet 90 in the Y- or X-direction.

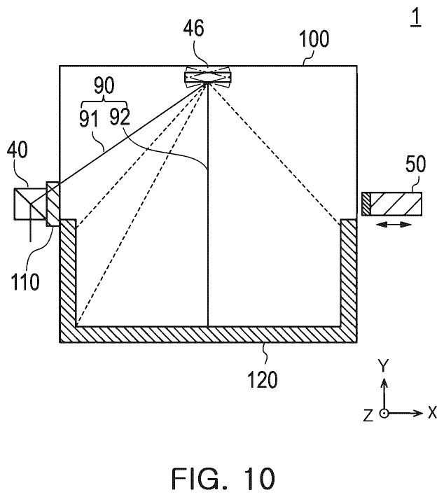

FIG. 10 illustrates an example configuration of a plasma processing apparatus 1 according to some example embodiments. FIG. 10 may be the same as or similar in some respects to FIG. 2B, and illustrates a chamber 100. The plasma processing apparatus 1 may additionally include a reflector 46.

The reflector 46 may be disposed, for example, in a rotatable plurality of axes within the chamber 100. The reflector 46 may reflect laser light transmitted through a view port 110. The reflector 46 may reflect the laser light to form or otherwise define a first portion 91 and a second portion 92 of the laser sheet 90. The first portion 91 and the second portion 92 may be formed in a position adjacent to each other with the reflector 46 interposed therebetween. The first portion 91 may be a portion among the laser sheet 90, from the view port 110 to the reflector 46. The second portion 92 may be a portion from the reflector 46 to an inner wall or damper 120 of the chamber 100 among the laser sheet 90. The reflector 46 reflects the main surface of the second portion 92, and may also be polarized in a direction intersecting the main surface of the first portion 91. For example, the second portion 92 may be formed in an observation region 50A. The plasma processing apparatus 1 may change with relative ease a direction of the laser sheet 90 by including this reflector 46. A dielectric multilayer film according to a wavelength may be provided on a surface of the reflector 46.

Accordingly, reflectivity may be improved, or scattering loss may be reduced or minimized. The reflector 46 may have a heating function or a cooling function.

The detection unit 50 may be configured to be movable, for example, in accordance with a direction of the reflector 46. Accordingly, excited luminescence in the observation region 50A may be detected with higher precision.

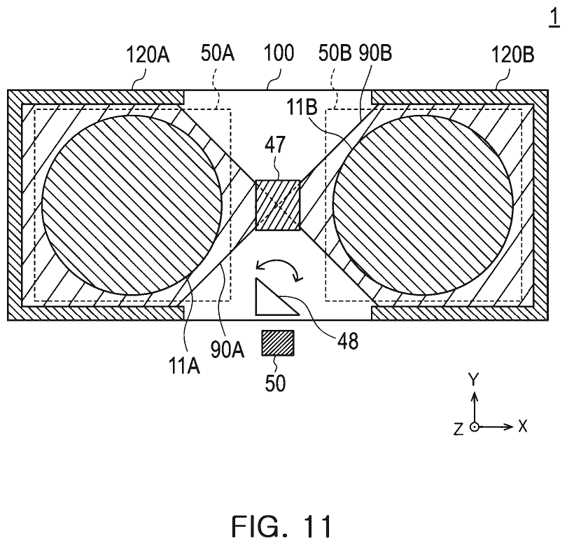

FIG. 11 illustrates an example configuration of a plasma processing apparatus 1, according to some example embodiments. FIG. 11 may be the same as or similar in some respects to FIG. 2B, and illustrates chamber 100, according to some example embodiments. This plasma processing apparatus 1 may include a plurality of stages (e.g., stages 11A and 11B).

Within the chamber 100, for example, a stage 11A and a stage 11B may be disposed side by side in an X-direction. Each of the stage 11A and the stage 11B may be configured to receive a substrate 70 for mounting the substrate 70. In the plasma processing apparatus 1 of FIG. 11, plasma processing may be performed on each of a plurality of substrates 70. For example, the plasma processing apparatus 1 may include two nozzles 23. One of the nozzles 23 may emit gas toward the stage 11A, and the other of the nozzles 23 may emit gas toward the stage 11B.

The laser light generation unit may include a beam splitter 47. For example, the beam splitter 47 may be disposed between the stage 11A and the stage 11B. The laser light generation unit may include a beam splitter 47. By this beam splitter 47, a laser sheet 90A and a laser sheet 90B may be formed. Main surfaces of the laser sheets 90A and 90B may be, for example, X-Y planes. A laser sheet 90A may be formed between the stage 11A and the nozzle 23. A laser sheet 90B may be formed between the stage 11B and the nozzle 23. A wavelength of the laser light comprising the laser sheet 90A and a wavelength of the laser light comprising the laser sheet 90B may be different from each other. In FIG. 11, reference numeral 50A may represent an observation region including at least a portion of regions between the stage 11A and the nozzle 23, respectively, and reference numeral 50B may represent an observation region including at least a portion of regions between the stage 11B and the nozzle 23. The beam splitter 47 may form a laser sheet 90A in the observation region 50A including at least a portion of regions between the mounting surface of the stage 11A and the nozzle 23. The beam splitter 47 may form a laser sheet 90B in the observation region 50B including at least a portion of regions between the mounting surface of the stage 11B and the nozzle 23.

The plasma processing apparatus 1 may have a flip lens instead of the beam splitter 47. The flip lens may be formed, for example, by switching the laser sheets 90A and 90B. For example, the flip lens may form the laser sheet 90A when the stage 11A is used, and may form the laser sheet 90B when the stage 11B is used.

For example, a prism 48 may be disposed between the stage 11A and the state 11B. for example, excited luminescence in the observation region 50A may be detected in the detection unit 50, for example, by interposing the prism 48. For example, by rotating the prism 48, the detection of the excited luminescence around the stage 11A and the detection of the excited luminescence around the stage 11B may be switched. In FIG. 11, reference numeral 120A may represent a damper disposed around the stage 11A on an inner wall of the chamber 100, and reference numeral 120B may represent a damper disposed around the stage 11B on the inner wall of the chamber 100.

Example embodiments have been described with reference to the plasma processing apparatus described above. It will be evident that various modifications and changes may be made to the plasma processing apparatus without departing from the scope and spirit of the present disclosure.

According to some example embodiments, the plasma processing apparatus 1 may also perform film forming processing, injection processing, and/or surface modification processing on the substrate 70 in addition to or instead of performing etching processing on a substrate 70. In some example embodiments, the plasma processing apparatus 1 may also perform cleaning processing on the substrate 70.

In addition, the detection unit 50 may also detect excited luminescence generated by by-products in the chamber 100 being excited by the laser sheet 90. The by-products are generated, for example, by plasma processing of the substrate 70. For example, when the plasma processing apparatus 1 cleans the nozzle 23 or the chamber 100, the detection unit 50 may detect the excited luminescence of by-products. Accordingly, it becomes possible to determine a state of impurities present in the chamber 100 and maintain the inside of the chamber 100 in a clean state.

In some example embodiments, the plasma processing apparatus 1 may include a plurality of laser light generation units 40, and/or may include a plurality of detection units 50.

In some example embodiments, the plasma processing apparatus 1 may not include a shutter 131.

In some example embodiments, and as discussed above, a gas including an active species raw material may be emitted from a nozzle 23 toward a stage 11. In some example embodiments, an active species 80 may also be emitted from a nozzle 23 toward a stage 11.

In some example embodiments, the processing units discussed with reference to the flow chart in FIG. 8 are discussed according to the processing contents in order to facilitate understanding of each processing. However, example embodiments are not limited thereto, and each processing operation may be divided into more sub-processing operations. In addition or alternatively, one or more processing operations may execute one or more additional processing operations.

The systems and methods for performing various processing, according to some example embodiments, may be realized using either a dedicated hardware circuit or a programmed (e.g., a specially programmed) computer. The program may be a computer-readable program code that may be provided by a computer-readable recording medium such as a flexible disk, a CD-ROM, and the like, for example, or may be provided online via a network such as the Internet, or the like. The program recorded on the computer-readable recording medium may be transferred to and stored in a memory device such as a hard disk, RAM, and/or ROM. In some example embodiments, the program may be provided as standalone application software, or may be incorporated into the software of the device as a function of the system.

As discussed above, according to some example embodiments of the inventive concepts, in the plasma processing apparatus and plasma processing method, planar excited luminescence may be detected in an observation region by a detection unit.

Accordingly, since a state of an active species around, adjacent, or in vicinity of a stage may be identified, plasma processing conditions may be adjusted in a relatively short time duration and/or with relative ease according to the state of the active species, making it possible to improve processing precision.

The various advantages and effects of the example embodiments are not limited to the above description, and other advantages may be easily understood from the example embodiments disclosed herein.

As described herein, any devices, systems, modules, portions, units, controllers, circuits, and/or portions thereof according to any of the example embodiments, and/or any portions thereof (including, without limitation, the stage system 10, the plasma generation system 20, the exhaust system 30, the laser light generation unit 40, the detection unit 50, the information processing unit 60, the band pass filter 52, the photoelectric conversion element 53, the pixel circuit 54, the communication interface 65, the operation display unit 66, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The example embodiments disclosed herein are to be considered as illustrative and not restrictive, and the intention is not to be limited to the details given herein. For example, the various elements or components may be combined or integrated in another system or certain features may be omitted, or not implemented.

What is claimed is:

1. A plasma processing apparatus, comprising
a stage having a mounting surface configured to mount a substrate;
an active species emitting unit configured to emit an active species or an active species raw material in a direction of the stage for performing plasma processing on the substrate;
a laser light generation unit configured to form a laser sheet in an observation region of the plasma processing apparatus, the observation region including at least a portion of a region between the mounting surface and the active species emitting unit; and
a detection unit configured to detect excited luminescence generated in the observation region,
wherein a quenching time period of the excited luminescence is 20 nanoseconds or less.

2. The plasma processing apparatus of claim 1, wherein the excited luminescence is generated by the active species excited by the laser sheet.

3. The plasma processing apparatus of claim 1, further comprising:
a chamber configured to accommodate the stage and the active species emitting unit.

4. The plasma processing apparatus of claim 3, wherein the chamber includes by-products generated by the plasma processing, and
the excited luminescence is generated based on the by-products excited by the laser sheet.

5. The plasma processing apparatus of claim 1, wherein the laser light generation unit is configured to form a main surface of the laser sheet in a direction intersecting the mounting surface.

6. The plasma processing apparatus of claim 1, wherein the laser light generation unit is configured to form a main surface of the laser sheet in a direction parallel to the mounting surface.

7. The plasma processing apparatus of claim 1, wherein the laser light generation unit is configured to change a wavelength of light comprising the laser sheet.

8. The plasma processing apparatus of claim 1, wherein the laser light generation unit comprises a light source configured to emit a beam of light and a lens unit configured to form the laser sheet from the beam of light.

9. The plasma processing apparatus of claim 1, further comprising:
a reflector,
wherein the laser sheet includes a first portion and a second portion adjacent to each other with the reflector therebetween, and
a main surface of the second portion is in a direction intersecting a main surface of the first portion.

10. The plasma processing apparatus of claim 1, wherein a width of the laser sheet is 50 mm or less.

11. The plasma processing apparatus of claim 1, further comprising:
a damper at or adjacent an end of the laser sheet.

12. The plasma processing apparatus of claim 1, wherein the detection unit faces a main surface of the laser sheet.

13. The plasma processing apparatus of claim 1, wherein the detection unit includes a single-photon avalanche diode (SPAD).

14. The plasma processing apparatus of claim 1, wherein the plasma processing apparatus includes a plurality of stages.

15. The plasma processing apparatus of claim 1, further comprising:
a shutter configured to switch between a closed state in which the shutter covers the mounting surface and an open state in which the shutter exposes the mounting surface.

16. The plasma processing apparatus of claim 2, further comprising:
an information processing unit configured to generate a first active species information regarding a state of the active species based on a first luminescence information regarding the excited luminescence captured at a first point in time.

17. The plasma processing apparatus of claim 16, wherein the information processing unit is configured to determine a first condition of the plasma processing based on the generated first active species information,
the information processing unit is configured to generate a second active species information regarding the state of the active species based on a second luminescence information regarding the excited luminescence captured at a second point in time later than the first point in time, and
the information processing unit is configured to change the first condition based on the generated second active species information.

18. The plasma processing apparatus of claim 17, wherein the information processing unit is configured to determine a second condition different from the first condition of the plasma processing.

19. A plasma processing apparatus, comprising:
a chamber;
a stage within the chamber and having a mounting surface configured to mount a substrate;
a nozzle within the chamber and configured to emit an active species or an active species raw material in a direction of the stage for performing plasma processing on the substrate;
a laser light generation unit adjacent to the chamber and configured to form a laser sheet in an observation region of the plasma processing apparatus, the observation region including at least a portion of a region between the mounting substrate and the nozzle; and
a detection unit configured to detect excited luminescence generated in the observation region,
wherein a quenching time period of the excited luminescence is 20 nanoseconds or less.

20. A plasma processing apparatus, comprising:
a chamber;
a plurality of stages within the chamber, each stage having a mounting surface configured to mount a substrate;
a plurality of nozzles within the chamber and configured to emit an active species or an active species raw material in a direction of each of the plurality of stages for performing plasma processing on the substrate;
a laser light generation unit between the plurality of stages and including a beam splitter or a flip lens configured to form a laser sheet in an observation region of the plasma processing apparatus, the observation region including at least a portion of a region between the mounting surfaces and the nozzles; and
a detection unit configured to detect excited luminescence generated in the observation region,
wherein a quenching time period of the excited luminescence is 20 nanoseconds or less.
